(19) United States
(12) Patent Application Publication
(10) Pub. No.: US 2026/0123243 A1
(43) Pub. Date: Apr. 30, 2026

(54) Display Device and Electronic Device

(71) Applicant: Samsung Display Co., Ltd., Yongin-si (KR)

(72) Inventors: Oh June Kwon, Yongin-si (KR); Woo Yong Sung, Yongin-si (KR); Seung Yong Song, Yongin-si (KR)

(73) Assignee: Samsung Display Co., Ltd., Yongin-si (KR)

(21) Appl. No.: 19/275,447

(22) Filed: Jul. 21, 2025

(30) Foreign Application Priority Data
Oct. 25, 2024 (KR) 10-2024-0147208

(51) Int. Cl. H10K 59/80

(52) U.S. Cl. CPC H10K 59/873

(57) ABSTRACT

A display device includes a display panel, a module hole penetrating the display panel in a display area of the display panel, and a blocking groove disposed on the display panel such that the blocking groove is disposed around the module hole. The blocking groove is recessed in the display area of the display panel and includes a first elongate portion, a second elongate portion disposed to face the first elongate portion, a first zigzag portion connected between a first side of the first horizontal portion and a first side of the second horizontal portion, and a second zigzag portion connected between a second side of the first horizontal portion and a second side of the second horizontal portion and disposed to face the first zigzag portion.

### CROSS-REFERENCE TO RELATED APPLICATION

This application claims priority from Korean Patent Application No. 10-2024-0147208 filed on Oct. 25, 2024, the disclosure of which is hereby incorporated by reference herein in its entirety.

### BACKGROUND

### 1. Technical Field

The present disclosure relates to a display device such as a display device included in an electronic device, and the structure of the display device in terms of its potential to prevent damage to an encapsulation layer of the display device when removing a protective tape.

### 2. Description of the Related Art

Various types of display devices that include a display module to provide image information have been developed. Such display devices may include an electronic module that receives an external signal or that provides an output signal to an external destination. One example of the electronic module of the display device is a camera module, and there has been an increasing demand for display devices capable of obtaining high-definition captured images. Thus, the increased significance of electronic modules has made ensuring their integrity ever more critical. Accordingly, there is a need to develop improvements to preserve the integrity of components of display devices.

### BRIEF SUMMARY

Aspects of the present disclosure provide a display device and electronic devices that include a display device that are capable of preventing damage to an encapsulation layer of the display device when removing a protective tape.

In one embodiment of the present disclosure, a display device is provided. The display device includes a display panel, a module hole penetrating the display panel in a display area of the display panel and a blocking groove disposed around the module hole to be recessed in the display area of the display panel. The blocking groove may include a first horizontal portion, a second horizontal portion disposed to face the first horizontal portion, a first zigzag portion connected between one side of the first horizontal portion and one side of the second horizontal portion, and a second zigzag portion connected between the other side of the first horizontal portion and the other side of the second horizontal portion and disposed to face the first zigzag portion.

In one embodiment of the present disclosure, a display device is provided. The display device includes a display panel, a module hole penetrating the display panel in a display area of the display panel and a blocking groove disposed around the module hole to be recessed in the display area of the display panel. The blocking groove may include a first protrusion, a second protrusion disposed to face the first protrusion, a first recess connected to one side of the first protrusion and one side of the second protrusion and a second recess connected to the other side of the first protrusion and the other side of the second protrusion and disposed to face the first recess.

In one embodiment of the present disclosure, a display device is provided. The display device includes a display panel, a module hole penetrating the display panel in a display area of the display panel and a plurality of blocking grooves disposed around the module hole to be recessed in the display area of the display panel. In plan view, two or more of the plurality of blocking grooves may have an elliptical shape with different eccentricities.

In one embodiment of the present disclosure, an electronic device is provided. The electronic device includes a display device that provides a screen. Further, the display device includes a display panel, a module hole penetrating the display panel in a display area of the display panel and a blocking groove disposed around the module hole to be recessed in the display area of the display panel. The blocking groove may include a first horizontal portion, a second horizontal portion disposed to face the first horizontal portion, a first zigzag portion connected between one side of the first horizontal portion and one side of the second horizontal portion and a second zigzag portion connected between the other side of the first horizontal portion and the other side of the second horizontal portion and disposed to face the first zigzag portion.

In accordance with the display device and the electronic device according to the present disclosure, it is possible to prevent damage to an encapsulation layer when removing a protective tape.

The advantageous effects of the embodiments of the present disclosure are not limited to the above-described effects and other advantageous effects will become apparent to those skilled in the art from the following description.

### BRIEF DESCRIPTION OF THE DRAWINGS

The above and other aspects and features of the present disclosure will become more apparent by reading the following detailed description of non-limiting embodiments thereof, and with reference to the accompanying drawings, in which:

FIG. 1 is a perspective view of a display device according to one embodiment of the present disclosure;

FIG. 2 is an exploded perspective view of the display device shown in FIG. 1;

FIG. 3 is a block diagram of the display device shown in FIG. 1;

FIG. 4 is a cross-sectional view of part of the display device taken along section line I-I′ of FIG. 2;

FIG. 5 is an enlarged cross-sectional view of a part of FIG. 4;

FIG. 6 is an enlarged cross-sectional view of a part of FIG. 5;

FIG. 7 is a cross-sectional view of part of the display device taken along line I-I′ of FIG. 2 according to one embodiment of the present disclosure;

FIG. 8 is a plan view of a display device according to one embodiment of the present disclosure;

FIG. 9 is a diagram of the first blocking groove of FIG. 8;

FIG. 10 is a plan view of a display device according to one embodiment of the present disclosure;

FIG. 11 is a diagram of the first blocking groove of FIG. 10;

FIG. 12 is a plan view of a display device according to one embodiment of the present disclosure;

FIG. 13 is a diagram illustrating the magnitude of resistance force of the protective tape in regions of the blocking groove when the protective tape is removed according to one embodiment of the present disclosure;

FIG. 14 is a perspective view of an electronic device to which a display device according to one embodiment is applied;

FIG. 15 is a block diagram of an electronic device according to one embodiment of the present disclosure; and

FIGS. 16, 17 and 18 are schematic diagrams of electronic devices according to various embodiments of the present disclosure.

### DETAILED DESCRIPTION

The present disclosure will now be described more fully hereinafter with reference to the accompanying drawings. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. Like reference numerals refer to like elements throughout the specification. In the accompanying figures, the thickness of layers and regions may be exaggerated for clarity.

Further, as used herein, the term “substantially” is intended to mean that slight deviations from absolute are included within the scope of the term so modified.

Although the terms “first”, “second”, etc. may be used herein to describe various elements, these elements, should not be limited by the use of such terms. These terms may be used to distinguish one element from another element in the context within which they are used. For instance, a first element discussed below may be termed a second element instead without departing from teachings of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of any one of the various embodiments of the present disclosure may be partially or entirely combined with one or more features of other embodiments and such combinations may be technically operable. As will be clearly appreciated by those skilled in the art, technically various interactions and operations are possible. Embodiments contemplated by the present disclosure may be practiced individually or in combination.

Hereinafter, specific exemplary embodiments will be described with reference to the accompanying drawings.

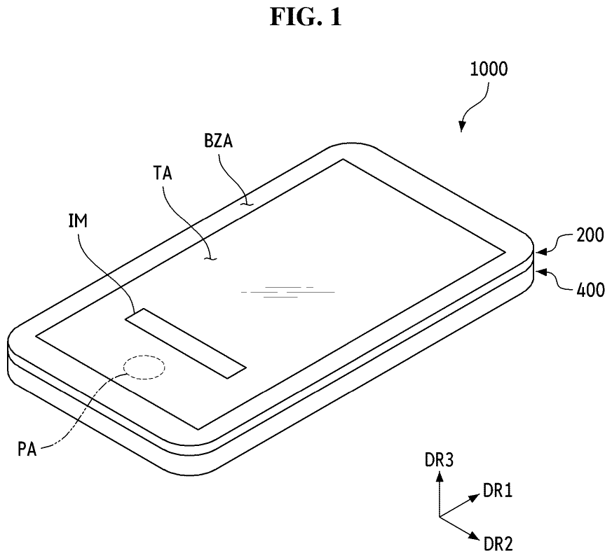

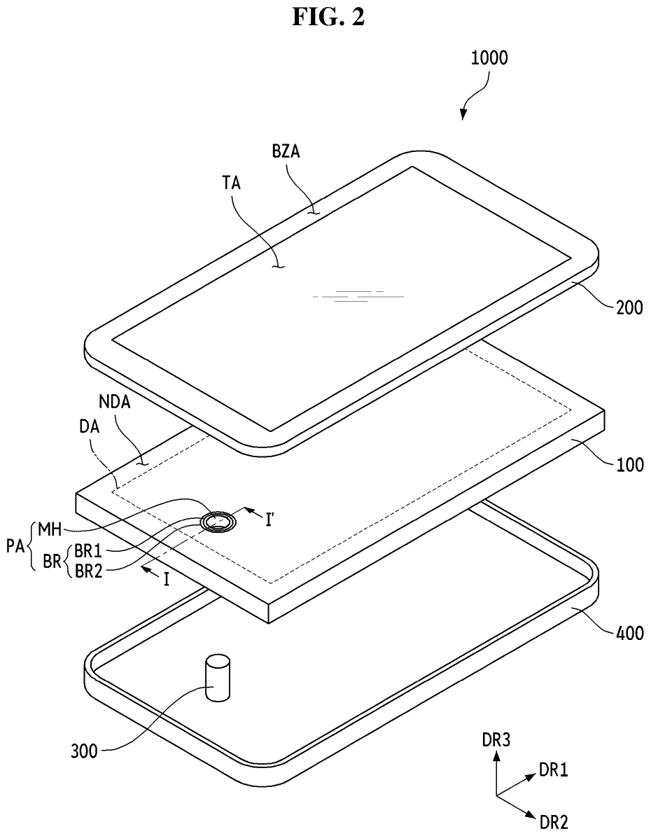

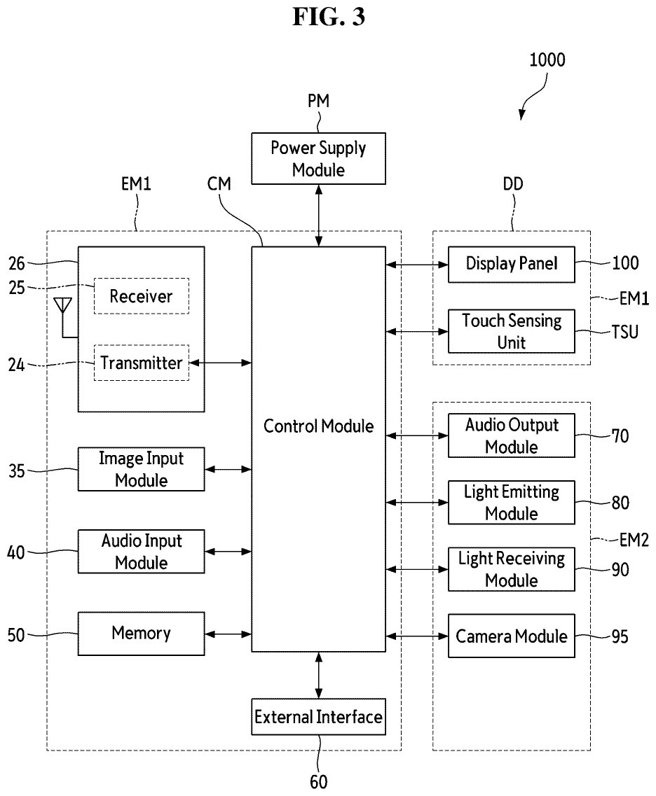

FIG. 1 is a perspective view of a display device according to one embodiment of the present disclosure. FIG. 2 is an exploded perspective view of the display device shown in FIG. 1. FIG. 3 is a block diagram of the display device shown in FIG. 1. Hereinafter, a display device according to one embodiment of the present disclosure will be described with reference to FIGS. 1 to 3.

A display device 1000 may be a device that is activated in response to an electrical signal. The display device 1000 may include various embodiments. For example, the display device 1000 may be a tablet, a laptop, a computer, a smart television, or the like. In the embodiment of FIG. 1, the display device 1000 is exemplarily illustrated as a smartphone.

As shown in FIG. 1, the display device 1000 may include a display surface that displays an image IM on its front surface. The display surface may be in a plane parallel to a plane defined by a first direction DR1 and a second direction DR2. The display surface may include a display area DA and a bezel area BZA adjacent to the display area DA.

The display device 1000 may display the image IM in the display area DA. In FIG. 1, an internet search bar is shown as one non-limiting example of the image IM. The display area DA may have a quadrilateral shape including boundaries parallel to each of the first direction DR1 and the second direction DR2. However, such shape is merely one example, and the display area DA may have various shapes and is not limited to any one embodiment.

As shown in FIGS. 1-2, the bezel area BZA may be adjacent to the display area DA. The bezel area BZA may surround the display area DA. However, in other examples, the bezel area BZA may be disposed adjacent to only one side of the display area DA or may be omitted. The shape, relative position, and other characteristics of the components of the display device 1000 shown in FIGS. 1-2 represent one example arrangement, and it should be appreciated that these characteristics may be modified to suit other embodiments.

A normal direction of the display surface may correspond to a thickness direction DR3 (hereinafter, referred to as a third direction) of the display device 1000. In the present embodiment, the front surface (or top surface) and the rear surface (or bottom surface) of each member may be defined based on a direction in which the image IM is displayed, with the front surface being the display surface. The front surface and the rear surface may be opposite to each other in the third direction DR3.

Meanwhile, directions indicated by the first to third directions DR1, DR2, and DR3 are relative concepts and may be converted to other directions. Hereinafter, the first to third directions DR1, DR2, and DR3 may refer to the same reference symbols in directions indicated by the first to third directions DR1, DR2, and DR3.

As shown in FIGS. 1 to 3, the display device 1000 may include a display panel 100, a window member 200, an electronic module 300, and a housing member 400. As shown in FIG. 3, the display device 1000 may further include a display module DD, a first electronic module EM1, a second electronic module EM2, and a power supply module PM. Some of the components shown in FIGS. 2 and 3 are omitted from other depictions of the display device 1000 and the display panel 100.

As shown in FIG. 3, the display module DD may include the display panel 100 and a touch sensing unit TSU. The display panel 100 may generate the image IM. The display panel 100 may detect a user's input applied from an external location. In such circumstances, the display panel 100 may further include a touch sensor, and the touch sensing unit TSU to be described later may be omitted.

The touch sensing unit TSU may detect the user's input applied from the outside. The user's input may include various types of external inputs such as a part of the user's body, light, heat, or pressure. In FIG. 2, the touch sensing unit TSU is omitted.

Meanwhile, in the present embodiment, the display panel 100 may be divided into the display area DA and a peripheral area NDA. As described above, the display area DA may be an area in which the image IM is generated. A plurality of pixels that generate the image IM may be disposed in the display area DA. A detailed description thereof is provided elsewhere in the present disclosure.

The peripheral area NDA may be adjacent to the display area DA. The peripheral area NDA may surround the display area DA. In some examples, a driving circuit, a driving line, or the like for driving the display area DA may be disposed in the peripheral area NDA.

Meanwhile, although not shown in the drawings, in some examples, a part of the peripheral area NDA in the display panel 100 may be bent. Accordingly, a part of the peripheral area NDA may face the front surface of the display device 1000, and another portion of the peripheral area NDA may face the rear surface of the display device 1000. Alternatively, in other examples, the peripheral area NDA of the display panel 100 may be omitted.

The display panel 100 according to one embodiment may include a module part PA provided in the display area DA. The module part PA may define a space in which an electronic module 300 is disposed. The module part PA may include a module hole MH and a blocking groove BR.

The module hole MH may penetrate the display panel 100. In some examples, the module hole MH may have a cylindrical shape having a height in the third direction DR3. The module hole MH may accommodate the electronic module 300. Since the display panel 100 includes the module hole MH, a thin display device may be implemented.

The blocking groove BR may be disposed on the display panel 100 so that the blocking groove BR is adjacent to the module hole MH. The blocking groove BR may be formed to be recessed from the front surface of the display panel 100. The blocking groove BR may have a closed curve shape surrounding the module hole MH in plan view, i.e., in a view where the display panel is viewed from a direction orthogonal to a surface of the display panel. For example, the blocking groove BR may have a circular ring shape surrounding the module hole MH. In some embodiments, the display device 1000 may include a plurality of blocking grooves. For example, the display panel 100 according to one embodiment may include a first blocking groove BR1 and a second blocking groove BR2. A detailed description of the module hole MH and the blocking groove BR is provided elsewhere in the present disclosure.

With reference to FIGS. 1 and 2, the window member 200 may provide the front surface of the display device 1000. The window member 200 may be disposed on the front surface of the display panel 100 to protect the display panel 100. For example, the window member 200 may include a glass substrate, a sapphire substrate, or a plastic film. The window member 200 may have a multilayer or single-layer structure. For example, the window member 200 may have a stacked structure of multiple plastic films bonded with an adhesive, or may have a stacked structure of a glass substrate and a plastic film bonded with an adhesive.

The window member 200 may be divided into a transmissive area TA and the bezel area BZA. The transmissive area TA may be an area corresponding to the display area DA. For example, the transmissive area TA may overlap an entire surface of the display area DA. The image IM displayed on the display area DA of the display panel 100 may be visually recognized from an external location through the transmissive area TA.

The bezel area BZA may define the shape of the transmissive area TA. The bezel area BZA may be adjacent to the transmissive area TA and may surround the transmissive area TA. The bezel area BZA may have a predetermined color. The bezel area BZA may cover the peripheral area NDA of the display panel 100 to block the peripheral area NDA from being visually recognized from an external location. In some alternative embodiments, the bezel area BZA may be omitted from the window member 200.

With reference to FIG. 3, the power supply module PM may supply power required for the overall operation of the display device 1000. The power supply module PM may include a conventional battery module.

Returning to FIGS. 1 and 2, the housing member 400 may be coupled to the window member 200. The housing member 400 may provide the rear surface of the display device 1000. The housing member 400 may be coupled to the window member 200 to define an internal space, and the display panel 100, the electronic module 300, and various components shown in FIG. 3 may be accommodated and otherwise received within the internal space. The housing member 400 may contain a material having relatively high rigidity. For example, the housing member 400 may include a plurality of frames and/or plates made of glass, plastic, or metal. The housing member 400 may provide stability to the display device 1000 and protect the components of the display device 1000 accommodated in the internal space from external impacts.

The electronic module 300 may include various functional modules for operating the display device 1000. As shown in FIG. 3, the electronic module 300 may include a first electronic module EM1 and a second electronic module EM2.

The first electronic module EM1 may be directly mounted on a motherboard electrically connected to the display module DD or may be mounted on a separate substrate and electrically connected to the motherboard through a connector (not shown) or the like.

The first electronic module EM1 may include a control module CM, a wireless communication module 26, an image input module 35, an audio input module 40, a memory 50, and an external interface 60. Some of these modules may not be mounted on the motherboard, but may be electrically connected to the motherboard through a flexible circuit board.

The control module CM may control the overall operation of the display device 1000. The control module CM may be a microprocessor. For example, the control module CM may activate or deactivate the display module DD. The control module CM may control other modules such as the image input module 35 or the audio input module 40 based on a touch signal received from the display module DD.

The wireless communication module 26 may transmit/receive wireless signals to/from other terminals using a Bluetooth or Wi-Fi line. The wireless communication module 26 may transmit/receive a voice signal using a general communication line. The wireless communication module 26 may include a transmitter 24 that modulates and transmits a signal to be transmitted, and a receiver 25 that demodulates a received signal.

The image input module 35 may process an image signal and convert it into image data displayable on the display module DD. The audio input module 40 may receive an external audio signal through a microphone in a recording mode, a voice recognition mode, and the like, and convert the external audio signal into electrical voice data.

The external interface 60 may serve as an interface connected to an external charger, a wired/wireless data port, a card socket (e.g., a memory card or a SIM/UIM card), and the like.

The second electronic module EM2 may include an audio output module 70, a light emitting module 80, a light receiving module 90, a camera module 95, and the like. These components may be directly mounted on the motherboard, may be mounted on a separate substrate and electrically connected to the display module DD through a connector (not shown) or the like, or may be electrically connected to the first electronic module EM1.

The audio output module 70 may convert audio data received from the wireless communication module 26 or audio data stored in the memory 50 and output it to the outside.

The light emitting module 80 may generate and output light. The light emitting module 80 may output infrared light. The light emitting module 80 may include an LED element. The light receiving module 90 may detect infrared light. The light receiving module 90 may be activated when infrared light at a predetermined level or higher is detected. The light receiving module 90 may include a CMOS sensor. After the infrared light generated by the light emitting module 80 is outputted, it may be reflected by an external object (e.g., the user's finger or face), and the reflected infrared light may be incident on the light receiving module 90. The camera module 95 may capture an external image.

The electronic module 300 shown in FIG. 2 may, in particular, be any one of the components of the second electronic module EM2. In this case, the remaining components of the first electronic module EM1 and the second electronic module EM2 may be disposed at other locations and may not be shown. However, this is illustrated as one example, and the electronic module 300 may be one or more of the modules constituting the first electronic module EM1 and the second electronic module EM2. Accordingly, in other embodiments, the electronic module 300 may include one or more of the modules of the first electronic module EM1, the second electronic module EM2, or a combination of the first electronic module EM1 and the second electronic module EM2.

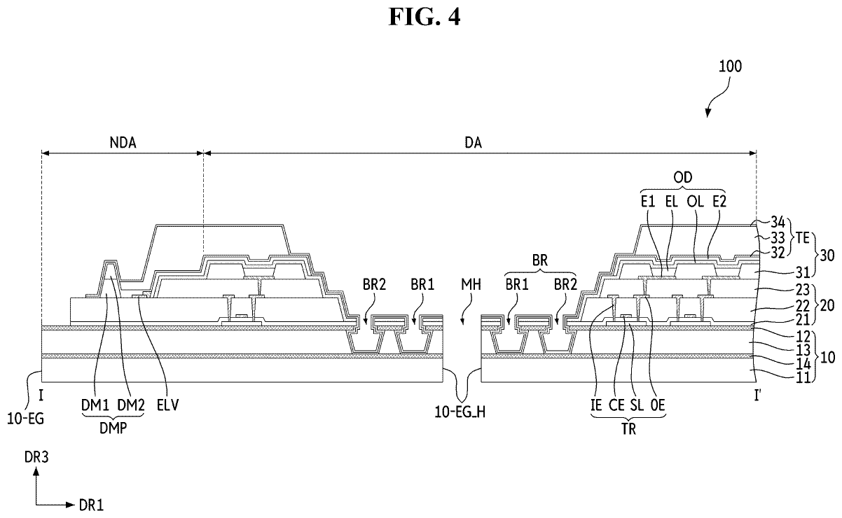

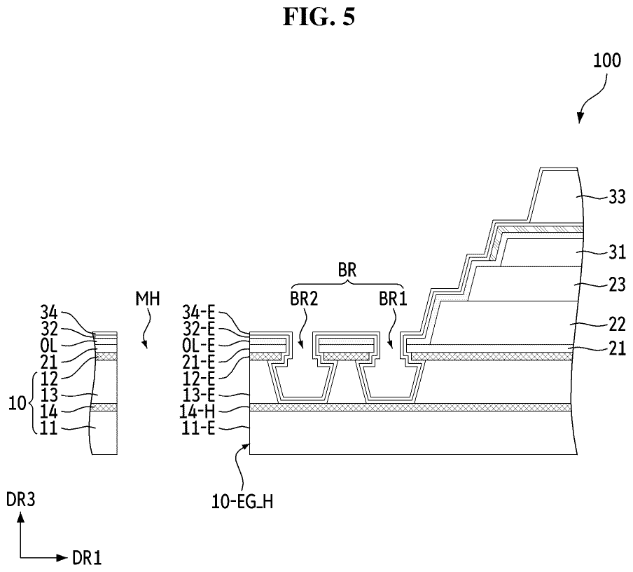

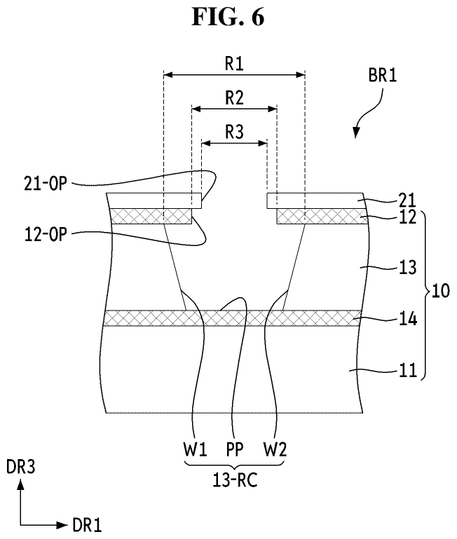

FIG. 4 is a cross-sectional view taken along section line I-I′ of FIG. 2. FIG. 5 is an enlarged cross-sectional view of a part of FIG. 4. FIG. 6 is a still further enlarged cross-sectional view of a part of FIG. 5. Hereinafter, the display panel 100 according to one embodiment of the present disclosure will be described with reference to FIGS. 4 to 6.

As shown in FIG. 4, the display panel 100 includes a base substrate 10, a driving element layer 20, and a display element layer 30. The base substrate 10, the driving element layer 20, and the display element layer 30 may be stacked along the third direction DR3.

The base substrate 10 may include a first base layer 11, a first barrier layer 12, a second base layer 13, and a second barrier layer 14.

The first base layer 11 may constitute the lower layer of the base substrate 10. The rear surface of the first base layer 11 may define the rear surface of the base substrate 10. In some examples, the first base layer 11 may be an insulating layer containing an organic material. The first base layer 11 may include flexible plastic. For example, the first base layer 11 may include polyimide (PI), polyethylene naphthalate (PEN), polyethylene terephthalate (PET), polyarylate, polycarbonate (PC), polyetherimide (PEI), or polyethersulfone (PES).

The first barrier layer 12 may include an inorganic material. The first barrier layer 12 may constitute the upper layer of the base substrate 10. The front surface of the first barrier layer 12 may define the front surface of the base substrate 10. The first barrier layer 12 may be an insulating layer containing an inorganic material. For example, the first barrier layer 12 may include silicon oxide, silicon nitride, amorphous silicon, or the like.

The second base layer 13 and the second barrier layer 14 may be disposed between the first base layer 11 and the first barrier layer 12. The second base layer 13 may contain the same material as the first base layer 11. The second barrier layer 14 may contain the same material as the first barrier layer 12.

The first base layer 11, the second base layer 13, the first barrier layer 12, and the second barrier layer 14 may be alternately arranged. The first barrier layer 12 and the second barrier layer 14 may be disposed on the second base layer 13 and the first base layer 11, respectively. Each of the first barrier layer 12 and the second barrier layer 14 may block external moisture or oxygen permeating through the first base layer 11 and the second base layer 13.

The driving element layer 20 may be disposed on the base substrate 10. The driving element layer 20 may include a plurality of insulating layers and a thin film transistor TR. Each of the insulating layers may contain an inorganic material and/or an organic material. The insulating layers may include first to third insulating layers 21, 22 and 23.

The thin film transistor TR may include a semiconductor pattern SL, a control electrode CE, an input electrode IE, and an output electrode OE. The thin film transistor TR may control a charge movement in the semiconductor pattern SL through the control electrode CE to allow an electrical signal inputted from the input electrode IE to be outputted through the output electrode OE.

The first insulating layer 21 may be disposed between the semiconductor pattern SL and the control electrode CE. In the present embodiment, the control electrode CE is shown as being disposed above the semiconductor pattern SL. However, this is merely one example arrangement, and the thin film transistor TR according to one embodiment of the present disclosure may include the semiconductor pattern SL disposed above the control electrode CE. Additionally, other relative arrangements are also contemplated.

The second insulating layer 22 may be disposed between the control electrode CE, and the input electrode IE and the output electrode OE. The input electrode IE and the output electrode OE may be disposed on the second insulating layer 22. As shown in FIG. 4, each of the input electrode IE and the output electrode OE may penetrate the first insulating layer 21 and the second insulating layer 22 to be connected to the semiconductor pattern SL. However, this is illustrated as an example, and in other examples, the input electrode IE and the output electrode OE may be directly connected to the semiconductor pattern SL.

The third insulating layer 23 may be disposed on the second insulating layer 22. The third insulating layer 23 may cover the thin film transistor TR. The third insulating layer 23 may electrically insulate the thin film transistor TR from the display element layer 30.

The display element layer 30 may include a light emitting element OD and a plurality of insulating layers. The insulating layers may include a fourth insulating layer 31 and an encapsulation layer TE.

The fourth insulating layer 31 may be disposed on the third insulating layer 23. In some examples, a plurality of openings may be defined in the fourth insulating layer 31. In a subset of these examples, the light emitting element OD may be disposed in each opening of the plurality of openings.

The light emitting element OD may include a first electrode E1, a second electrode E2, a light emitting layer EL, and a charge control layer OL. The first electrode E1 may be disposed on the driving element layer 20. The first electrode E1 may penetrate the third insulating layer 23 to be electrically connected to the thin film transistor TR. In some examples, a plurality of the first electrodes E1 may be provided. At least a part of each electrode of the plurality of first electrodes E1 may be exposed by respective openings in the fourth insulating layer 31.

The second electrode E2 may be disposed above the first electrode E1. The second electrode E2 may have an integral structure, i.e., monolithic and may extend over an extent that overlaps the plurality of first electrodes and the fourth insulating layer 31. In some examples, the second electrode E2 may overlap an entirety of the fourth insulating layer 31. When a plurality of the light emitting elements OD are provided, the same voltage may be applied to the second electrode E2 in each of the plurality of light emitting elements OD. Accordingly, a separate patterning process to form the second electrode E2 may be omitted. Meanwhile, this is illustrated as an example, and a plurality of the second electrodes E2 may be provided to correspond to the respective openings.

The light emitting layer EL may be disposed between the first electrode E1 and the second electrode E2. A plurality of the light emitting layers EL may be provided and respectively disposed in the openings. The light emitting element OD may generate light by activating the light emitting layer EL according to a potential difference between the first electrode E1 and the second electrode E2.

The charge control layer OL may be disposed between the first electrode E1 and the second electrode E2. The charge control layer OL may be disposed adjacent to the light emitting layer EL. The charge control layer OL may be disposed between the light emitting layer EL and the second electrode E2. However, the present disclosure is not limited thereto, and in some examples, the charge control layer OL may be disposed between the light emitting layer EL and the first electrode E1, or may be provided as a plurality of layers stacked along the third direction DR3 with the light emitting layer EL interposed therebetween.

The charge control layer OL may have an integral structure overlapping an entire surface of the base substrate 10 without a separate patterning process. The charge control layer OL may also be disposed in one or more regions other than, i.e., separate from the openings formed in the fourth insulating layer 31.

The encapsulation layer TE may be disposed on the light emitting element OD. The encapsulation layer TE may include an inorganic film and/or an organic film. In the present embodiment depicted in FIG. 4, the encapsulation layer TE may include a first inorganic film 32, an organic film 33, and a second inorganic film 34.

Each of the first inorganic film 32 and the second inorganic film 34 may contain an inorganic material. For example, each of the first inorganic film 32 and the second inorganic film 34 may contain at least one of aluminum oxide, silicon oxide, silicon nitride, silicon oxynitride, silicon carbide, titanium oxide, zirconium oxide, or zinc oxide. The first inorganic film 32 and the second inorganic film 34 may contain the same or different materials.

The organic film 33 may be disposed between the first inorganic film 32 and the second inorganic film 34. The organic film 33 may contain an organic material. For example, the organic film 33 may include at least one of epoxy, polyimide (PI), polyethylene terephthalate (PET), polycarbonate (PC), polyethylene (PE), or polyacrylate.

One or both of the first inorganic film 32 and the second inorganic film 34 may have an integral structure that is disposed across an entire surface of the display panel 100. Each of the first inorganic film 32 and the second inorganic film 34 may partially overlap the organic film 33. Accordingly, the first inorganic film 32 and the second inorganic film 34 may be spaced apart from each other in the third direction DR3 with the organic film 33 interposed therebetween in a first region, and may be in direct contact in the third direction DR3 in a second region separate from the first region.

Meanwhile, as shown in FIG. 4, the display panel 100 may further include a dam portion DMP. The dam portion DMP may extend along the edge of the display area DA (see FIGS. 2 and 4). In some examples, the dam portion DMP may surround the display area DA.

The dam portion DMP may include a first dam DM1 and a second dam DM2. In some examples, the first dam DM1 may contain the same material as the third insulating layer 23. In some examples, the first dam DM1 may be formed simultaneously with the third insulating layer 23 and may be disposed on the same layer as the third insulating layer 23.

The second dam DM2 may be stacked on the first dam DM1. In some examples, the second dam DM2 may contain the same material as the fourth insulating layer 31. In some examples, the second dam DM2 may be formed simultaneously with the fourth insulating layer 31 and may be disposed on the same layer as the fourth insulating layer 31. Meanwhile, this is illustrated as an example, and the dam portion DMP may have a single-layer structure and is not limited to any one embodiment.

The dam portion DMP may define a region in which a liquid organic material is spread in the process of forming the organic film 33. The organic film 33 may be formed by applying a liquid organic material onto the first inorganic film 32 using an inkjet method, and in this case, the dam portion DMP may set the boundary of a region where the liquid organic material is disposed and may prevent the liquid organic material from overflowing to areas outside of the dam portion DMP.

Hereinafter, a region in which the module hole MH and the blocking groove BR are defined will be described in detail with reference to FIGS. 5 and 6. The module hole MH penetrates the display panel 100 along the third direction DR3. As the module hole MH is defined in the display area DA, the module hole MH penetrates not only the base substrate 10 but also some of the layers included in the display area DA.

Specifically, in the embodiment depicted in FIG. 5, the module hole MH penetrates the base substrate 10 and several other layers of the display panel 100. An inner surface 10-EG_H of the module hole MH may be defined by the ends of the plurality of layers. At the penetration location, ends of the layers of the base substrate 10, including of the first base layer 11, the first barrier layer 12, the second base layer 13, and the second barrier layer 14 are defined. Namely, an end 11-E of the first base layer, an end 12-E of the first barrier layer, an end 13-E of the second base layer, and an end 14-E of the second barrier layer, respectively.

Along inner surface 10-EG_H, the end 11-E of the first base layer, the end 12-E of the first barrier layer, the end 13-E of the second base layer, the end 14-E of the second barrier layer, an end 21-E of the first insulating layer, an end OL-E of the charge control layer, an end 32-E of the first inorganic film, and an end 34-E of the second inorganic film may be aligned in the third direction DR3. Accordingly, the module hole MH may have a uniform width along its length. In some examples, the module hole may have a cylindrical shape with a height along the third direction DR3. In other examples, and at least some of the ends of the respective layers defining the module hole MH may be unaligned with each other such that the module hole MH has an irregular shape along its length in the third direction DR3.

As shown in FIG. 5, the blocking groove BR may include the first blocking groove BR1 and the second blocking groove BR2. In plan view, i.e., viewing the display panel 100 in a direction DR3 facing a plane defined by the first direction DR1 and the second direction DR2, the first blocking groove BR1 may surround and enclose the module hole MH, and the second blocking groove BR2 may surround and enclose the first blocking groove BR1. In some examples, and as shown in FIG. 5, the module hole MH, the first blocking groove BR1, and the second blocking groove BR2 may be spaced apart from each other. In this manner, the second blocking groove BR2 may be at a different distance, e.g., further from the module hole MH than the first blocking groove BR1. Further, a length of the second blocking groove BR2 may be longer than a length of the first blocking groove BR1, i.e., in plan view, the length of the enclosed shape. In some embodiments, the blocking groove BR may further include at least one blocking groove, e.g. a third blocking groove, spaced apart from the second blocking groove BR2 and surrounding the second blocking groove BR2.

Hereinafter, since the cross-sectional shapes, i.e., shapes in a plane coincident with the first direction DR1 and the third direction DR3, of the first blocking groove BR1 and the second blocking groove BR2 are substantially the same in the embodiment depicted in FIG. 5, the shape of the first blocking groove BR1 will be described as representative, and the shape of the second blocking groove BR2 should be understood to include substantially the same characteristics as the first blocking groove BR1. In other embodiments, the blocking groove may include the first blocking groove BR1 having a different cross-section than the second blocking groove BR2.

The first blocking groove BR1 may be recessed from the front surface of the display panel 100 and in a direction opposite the third direction DR3, i.e., in a direction toward the rear surface of the display panel 100. However, the first blocking groove BR1 does not penetrate an entirety of the base substrate 10. Accordingly, the first blocking groove BR1 penetrates the front surface of the display panel 100 but does not penetrate the rear surface thereof.

The first blocking groove BR1 may be formed by removing at least a part of the base substrate 10. For example, the first blocking groove BR1 may be formed by removing at least a part of the first barrier layer 12 and the second base layer 13. The first blocking groove BR1 may penetrate the first barrier layer 12 and the second base layer 13 in the third direction DR3. However, the present disclosure is not limited thereto, and in some examples, the second base layer 13 may be only partially removed and not fully penetrated. The first base layer 11 and the second barrier layer 14 may be left intact, i.e., not removed by the first blocking groove BR1. Therefore, oxygen or moisture entering from below the first base layer 11 may be prevented from permeating into the first blocking groove BR1 by the second barrier layer 14.

With reference to FIG. 6, the first blocking groove BR1 according to one embodiment of the present disclosure may be defined in the base substrate 10 and may include an inner surface with an undercut shape. In FIG. 6, the first inorganic film 32 and the second inorganic film 34 are omitted for ease of description. The first blocking groove BR1 may include a recessed portion 13-RC and at least one through portion. In some examples, the through portion is through portion 12-OP of the first barrier layer. In other examples, and as shown in FIG. 6, the through portion of the first blocking groove BR1 includes two through portions, through portion 21-OP of the first insulating layer and through portion 12-OP of the first barrier layer. It should be appreciated that other variations of the through portion are also contemplated.

The recessed portion 13-RC may be defined in the second base layer 13 such that the recessed portion 13-RC is in communication with the through portion 12-OP, 21-OP. The recessed portion 13-RC may be recessed from the front surface of the second base layer 13. The recessed portion 13-RC may be defined by a base with a flat surface PP, a first side surface W1, and a second side surface W2. Meanwhile, although the first side surface W1 and the second side surface W2 are shown separately for ease of description, the first side surface W1 and the second side surface W2 may be a connected integral surface, e.g., a circumferentially enclosed surface.

The flat surface PP may be a surface recessed from the front surface of the second base layer 13 and may be located at the rear surface of the second base layer 13. In some examples, the flat surface PP may be spaced apart from the rear surface of the second base layer 13 in the third direction DR3. In some embodiments of the present disclosure, the flat surface PP may be a part of the top surface of the second barrier layer 14. Each of the first side surface W1 and the second side surface W2 may be connected to the flat surface PP. Each of the first side surface W1 and the second side surface W2 may be inclined relative to the flat surface PP. In the recessed portion 13-RC, an angle formed between the flat surface PP and each of the first side surface W1 and the second side surface W2 may be 90 degrees or more.

As shown in FIG. 6, the through portion 12-OP of the first barrier layer 12 (or the through portion 12-OP, 21-OP of the combined first barrier layer and first insulating layer) and the recessed portion 13-RC may form an undercut shape. Specifically, the first barrier layer 12 may overlap/overhang the through portion 13-OP of the second base layer. The first barrier layer 12 protrudes more inward than the recessed portion 13-RC to cover at least a part of the recessed portion 13-RC. A width R2 of the through portion 12-OP of the first barrier layer 12 in the first direction DR1 may be smaller than a width R1 of the recessed portion 13-RC in the first direction DR1. In some examples, such as the arrangement shown in FIG. 6, a width R3 of the through portion 21-OP may be smaller than the width R2 of the through portion 12-OP.

The width of the recessed portion 13-RC measured in the first direction DR1 at the same height as the top surface of the second base layer 13 may be greater than the width of the recessed portion 13-RC measured in the first direction DR1 at the same height as the bottom surface of the second base layer 13. In some examples, the recessed portion 13-RC may have a truncated cone shape. However, the embodiments contemplated by the present disclosure are not limited thereto. For instance, in other examples, the recessed portion 13-RC may have a truncated pyramid shape or a truncated elliptical cone shape.

Returning to FIGS. 4 and 5, each of the first inorganic film 32 and the second inorganic film 34 may, in some examples, extend to a region where the first and second blocking grooves BR1 and BR2 are disposed.

The first inorganic film 32 and the second inorganic film 34 may be disposed in a region adjacent to the first and second blocking grooves BR1 and BR2 and along the inner surfaces of the first and second blocking grooves BR1 and BR2. Accordingly, the inside of the first and second blocking grooves BR1 and BR2 may be covered by the first inorganic film 32 and the second inorganic film 34.

The charge control layer OL may have a discontinuous end in a region adjacent to the first and second blocking grooves BR1 and BR2 and may not overlap the blocking groove BR. The discontinuous end of the charge control layer OL adjacent to the blocking groove BR may be covered by the first inorganic film 32 and the second inorganic film 34. Similarly, in embodiments that include the first insulating layer 21, the first insulating layer may have a discontinuous end in a region adjacent to the first and second blocking grooves BR1 and BR2 and may not overlap the blocking groove BR. And, the discontinuous end of the first insulating layer 21 adjacent to the blocking groove BR may be covered by the first inorganic film 32 and the second inorganic film 34.

As shown in FIGS. 4 and 5, the base substrate 10, the driving element layer 20, and the display element layer 30 may each have a discontinuous end in a region adjacent to the module hole MH. The discontinuous ends may be exposed through the module hole MH. Moisture or oxygen from outside the display panel 100 may enter the base substrate 10, the driving element layer 20, and the display element layer 30 through the exposed ends of those layers.

According to some embodiments, by defining the first and second blocking grooves BR1 and BR2 adjacent to the module hole MH, a permeation path of oxygen or moisture entering from the module hole MH may be blocked. Specifically, the first blocking groove BR1 primarily blocks oxygen and/or moisture entering through the module hole MH from further penetrating into the display panel 100, and the second blocking groove BR2 secondarily blocks such oxygen and/or moisture. Specifically, the first blocking groove BR1 may separate a portion of the charge control layer OL disposed between the module hole MH and the first blocking groove BR1 from a portion of the charge control layer OL disposed outside the first blocking groove BR1. Accordingly, even if external oxygen or moisture enters through the module hole MH, it does not spread to areas radially outside of the first blocking groove BR1, and thus damage to the driving element layer 20 or the display element layer 30 present outside the first blocking groove BR1 may be reliably prevented. Further, because the second blocking groove BR2 has the same structure as the first blocking groove BR1, the second blocking groove BR2 may perform a similar function as the first blocking groove BR1.

In addition, according to some embodiments, the first inorganic film 32 and the second inorganic film 34 may cover regions between the module hole MH and the first blocking groove BR1, between the first and second blocking grooves BR1 and BR2, inside the first and second blocking grooves BR1 and BR2, and outside the second blocking groove BR2. Organic layers, e.g., the charge control layer OL, disconnected adjacent to the first and second blocking grooves BR1 and BR2 may be covered by the first inorganic film 32 and the second inorganic film 34. Accordingly, the extent of blocking of the inflow of moisture and/or oxygen may be improved.

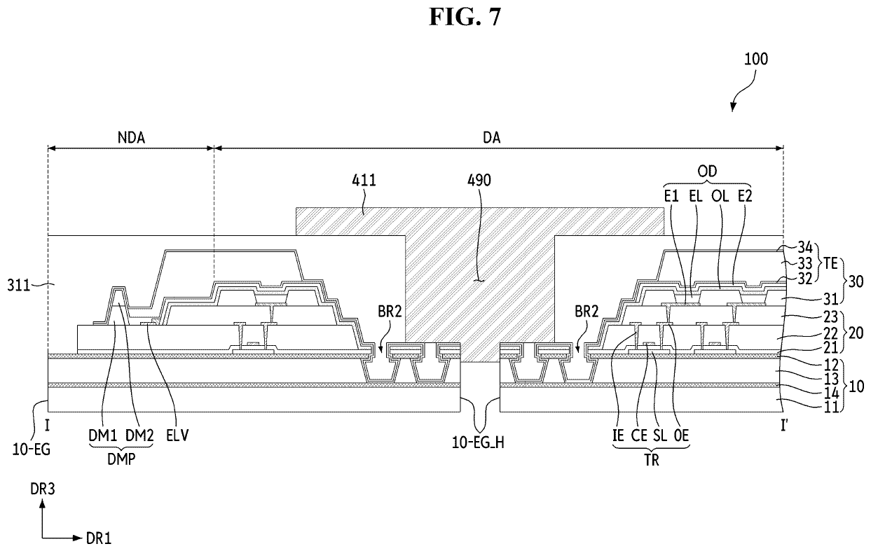

FIG. 7 is a cross-sectional view of a display panel 100 according to another embodiment, the cross-section being taken along line I-I′ of FIG. 2. In FIG. 7, like reference numerals refer to like elements shown in FIG. 4, unless otherwise indicated.

The display device of FIG. 7 differs from the display device of FIG. 4 described above in that it further includes a protective film 311 and a protective tape 411.

As shown in FIG. 7, the protective film 311 may be disposed on the encapsulation layer TE. The protective film 311 may define a through hole 490 that exposes the module hole MH and the blocking groove BR. The protective film 311 may serve to protect the encapsulation layer TE in the manufacturing process of the display panel 100.

The protective tape 411 may be disposed on the protective film 311. For example, the protective tape 411 may be disposed on the protective film 311 to cover the through hole 490 of the protective film 311. The protective tape 411 may be in contact with the encapsulation layer TE in the through hole 490. For example, the protective tape 411 may be attached to the encapsulation layer TE within the through hole 490.

The protective tape 411 may serve to protect the encapsulation layer TE exposed through the module hole MH when etching the rear surface of the first base layer 11. For example, the process of etching the rear surface of the first base layer 11 may be performed to reduce the thickness of the base substrate 10, and during this etching process, the protective tape 411 may block an etchant from permeating into the light emitting element through the module hole MH.

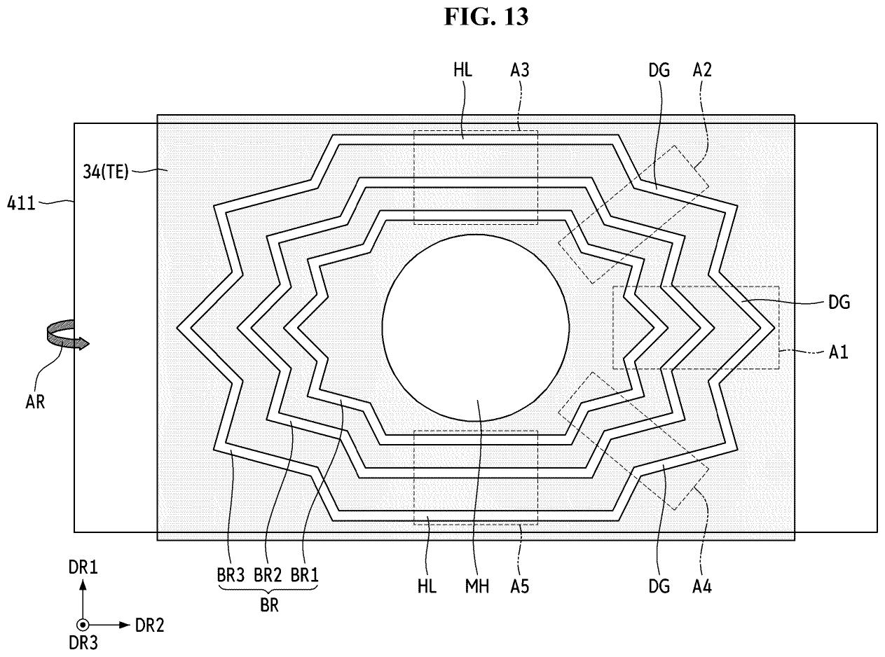

The protective film 311 and the protective tape 411 may serve a temporary function. Specifically, the protective film 311 and the protective tape 411 may be removed after the display panel 100 is manufactured. In some embodiments, the protective tape 411 may be removed along the second direction DR2, as shown in FIG. 13, for example. However, with the use of previously known display panel configurations, when the protective tape is removed from the front surface, it has been observed that at least a portion of the encapsulation layer attached to the protective tape may be removed with the protective tape due to an adhesive force between the protective tape and the encapsulation layer. For example, when the protective tape is removed, at least a portion of the encapsulation layer TE attached thereto may be separated with the protective tape, thereby damaging the encapsulation layer. Hereinafter, according to some embodiments of the present disclosure, a display device capable of solving such a problem is described in detail.

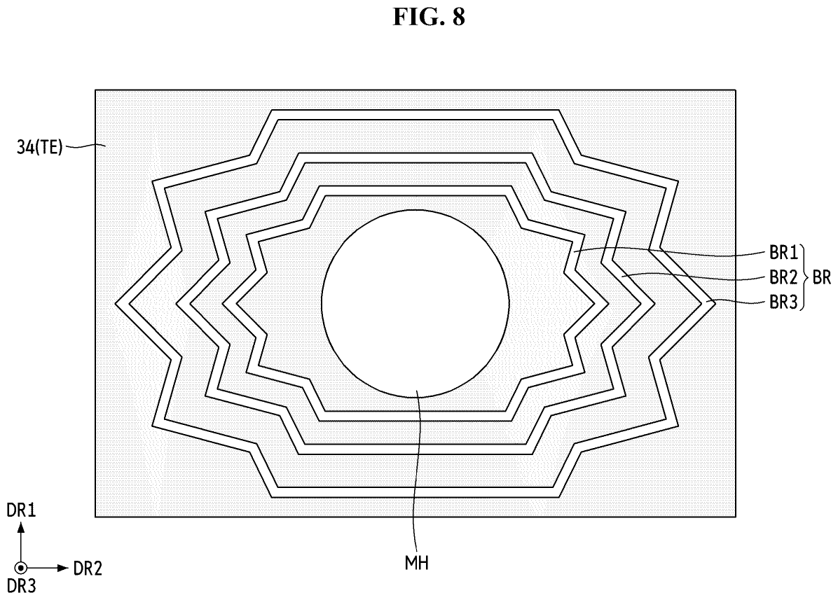

FIG. 8 is a plan view, i.e., a view in a direction orthogonal to a plane coincident with a surface of the display panel 100, of a portion of a display device according to one embodiment. Specifically, FIG. 8 is a plan view of the module hole MH and the blocking groove BR around the module hole MH. In some examples, cross-sectional details of the blocking groove BR and the module hole MH may be as described above.

As shown in FIG. 8, the blocking groove BR may be disposed on the display panel 100 such that the blocking groove BR is disposed around the module hole MH. In some examples, and as shown in FIG. 8, the blocking groove BR may include the first blocking groove BR1, the second blocking groove BR2, and a third blocking groove BR3.

The first blocking groove BR1 may be disposed adjacent to the module hole MH. For example, the first blocking groove BR1 may be disposed between the module hole MH and the second blocking groove BR2. In plan view, the first blocking groove BR1 may have a closed curve shape, i.e., enclosed shape that surrounds the module hole MH.

The second blocking groove BR2 may be disposed adjacent to the first blocking groove BR1. For example, the second blocking groove BR2 may be disposed between the first blocking groove BR1 and the third blocking groove BR3. In plan view, the second blocking groove BR2 may have a closed curve shape that surrounds the first blocking groove BR1 and the module hole MH.

The third blocking groove BR3 may be disposed adjacent to the second blocking groove BR2. In plan view, the second blocking groove BR2 may have a closed curve shape that surrounds the first blocking groove BR1, the second blocking groove BR2, and the module hole MH.

In plan view, a part or parts of the first blocking groove BR1 may have a zigzag shape. In some examples, and as depicted in FIG. 8, the first blocking groove BR1, the second blocking groove BR2, and the third blocking groove BR3 may have the same shape.

In plan view, the length of the second blocking groove BR2 may be greater than the length of the first blocking groove BR1 and less than the length of the third blocking groove BR3.

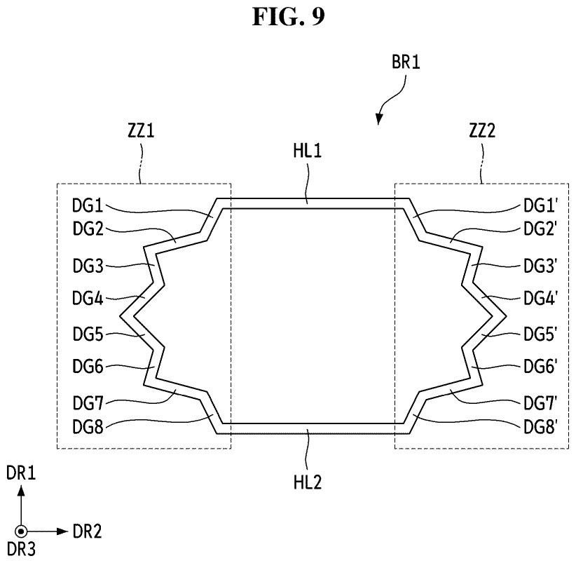

The shape of the blocking groove BR will now be described in more detail with reference to FIG. 9. Here, since the first blocking groove BR1, the second blocking groove BR2, and the third blocking groove BR3 have the same shape, the shape of the first blocking groove BR1 will be described in detail and will be considered as representative of the other blocking grooves, i.e., the second blocking groove BR2 and the third blocking groove BR3.

FIG. 9 is a diagram of the first blocking groove BR1 of FIG. 8 with the shape being as the first blocking groove BR1 would appear in plan view.

As shown in FIG. 9, the first blocking groove BR1 may include a first horizontal portion HL1, a second horizontal portion HL2, a first zigzag portion ZZ1, and a second zigzag portion ZZ2. In some examples, the first horizontal portion HL1, the second horizontal portion HL2, the first zigzag portion ZZ1, and the second zigzag portion ZZ2 may be integrally, i.e. monolithically formed. Each horizontal portion may also be referred to as an elongate portion. For instance, the first horizontal portion HL1 may be a first elongate portion and the second horizontal portion HL2 may be a second elongate portion.

The first horizontal portion HL1 may have the shape of a line extending along the second direction DR2. In some examples, the shape of the first horizontal portion HL1 is a linear line. In a subset of these examples, such as in the first blocking groove BR1 of FIG. 9, the shape of the first horizontal portion HL1 is entirely linear. For example, when the protective tape 411 is removed along the second direction DR2, the first horizontal portion HL1 may have the shape of a line extending along the same direction (e.g., the second direction DR2) as the removal direction of the protective tape 411.

The second horizontal portion HL2 may be disposed to face the first horizontal portion HL1. For example, the second horizontal portion HL2 may be disposed to face the first horizontal portion HL1 in the first direction DR1. When the protective tape 411 is disposed on the display panel 100, the protective tape 411 is removable through a pulling action along the second direction DR2. When the protective tape 411 is removed along the section direction DR2, the second horizontal portion HL2 and the first horizontal portion HL1 as depicted in FIG. 9 are disposed to face each other along the first direction DR1 perpendicular to the second direction DR2. In this manner, the second horizontal portion HL2 and the first horizontal portion HL1 may have the shape of a line extending along the second direction DR2. Accordingly, when the protective tape 411 is removed along the second direction DR2, the line shape of the second horizontal portion HL2 and the first horizontal portion HL1 may extend along the same direction as the removal direction of the protective tape 411. In some examples, the second horizontal portion HL2 may be aligned with the first horizontal portion HL1. In a subset of these examples, the second horizontal portion HL2 and the first horizontal portion HL1 may be disposed in parallel. For instance, the second horizontal portion HL2 and the first horizontal portion HL1 may be disposed in parallel along the second direction DR2.

As shown in FIG. 9, the first zigzag portion ZZ1 may be disposed between one side, i.e., a first side of the first horizontal portion HL1 and one side, i.e. a first side of the second horizontal portion HL2. One side of the first zigzag portion ZZ1 may be connected to one side of the first horizontal portion HL1, and the other side of the first zigzag portion ZZ1 may be connected to one side of the second horizontal portion HL2. The first zigzag portion ZZ1 may be shaped with bends to define a zigzag form. To this end, according to one embodiment, the first zigzag portion ZZ1 may include a plurality of diagonal portions DG1, DG2, DG3, DG4, DG5, DG6, DG7, and DG8 respectively connected to each other at predetermined angles to form a zigzag shape. For example, the first zigzag portion ZZ1 may include a first diagonal portion DG1, a second diagonal portion DG2, a third diagonal portion DG3, a fourth diagonal portion DG4, a fifth diagonal portion DG5, a sixth diagonal portion DG6, a seventh diagonal portion DG7, and an eighth diagonal portion DG8. Here, the first to eighth diagonal portions DG1 to DG8 may be integrally formed.

Each of the diagonal portions DG1 to DG8 of the first zigzag portion ZZ1 may have a shape inclined in a diagonal direction with respect to the second direction DR2, so as to form an oblique angle, i.e., a non-90 degree angle with respect to the second direction DR2. For example, the first direction DR1 is a direction that perpendicularly intersects the removal direction (e.g., the second direction DR2) of the protective tape 411 at 90 degrees, and each of the diagonal portions DG1 to DG8 of the first zigzag portion ZZ1 may be disposed to have an inclination that is not parallel to the first direction DR1.

The first diagonal portion DG1 may be connected to the first horizontal portion HL1 and the second diagonal portion DG2. The second diagonal portion DG2 may be connected to the first diagonal portion DG1 and the third diagonal portion DG3. The third diagonal portion DG3 may be connected to the second diagonal portion DG2 and the fourth diagonal portion DG4. The fourth diagonal portion DG4 may be connected to the third diagonal portion DG3 and the fifth diagonal portion DG5. The fifth diagonal portion DG5 may be connected to the fourth diagonal portion DG4 and the sixth diagonal portion DG6. The sixth diagonal portion DG6 may be connected to the fifth diagonal portion DG5 and the seventh diagonal portion DG7. The seventh diagonal portion DG7 may be connected to the sixth diagonal portion DG6 and the eighth diagonal portion DG8. The eighth diagonal portion DG8 may be connected to the seventh diagonal portion DG7 and the second horizontal portion HL2.

With continued reference to FIG. 9, the second zigzag portion ZZ2 may be disposed between the other side, i.e., a second side of the first horizontal portion HL1 and the other side, i.e., a second side of the second horizontal portion HL2. One side of the second zigzag portion ZZ2 may be connected to the other side of the first horizontal portion HL1, and the other side of the second zigzag portion ZZ2 may be connected to the other side of the second horizontal portion HL2. The second zigzag portion ZZ2 may face the first zigzag portion ZZ1 in the second direction DR2. In some examples, the second zigzag portion ZZ2 may have a shape symmetrical to the first zigzag portion ZZ1 with respect to an imaginary line (hereinafter, a vertical symmetry line) that passes through the centers of the first horizontal portion HL1 and the second horizontal portion HL2 and is parallel to the first direction DR1. The second zigzag portion ZZ2 may be shaped to define a zigzag form. To this end, according to one embodiment, the second zigzag portion ZZ2 may include a plurality of diagonal portions DG1′, DG2′, DG3′, DG4′, DG5′, DG6′, DG7′, and DG8′ respectively connected to each other at a predetermined angle to form a zigzag shape. For example, the second zigzag portion ZZ2 may include a first diagonal portion DG1′, a second diagonal portion DG2′, a third diagonal portion DG3′, a fourth diagonal portion DG4′, a fifth diagonal portion DG5′, a sixth diagonal portion DG6′, a seventh diagonal portion DG7′, and an eighth diagonal portion DG8′. Here, the first to eighth diagonal portions DG1′ to DG8′ may be integrally formed.

Each of the diagonal portions DG1′ to DG8′ of the second zigzag portion ZZ2 may have a shape inclined in a diagonal direction with respect to the second direction DR2, so as to form an oblique angle, i.e., non-90 degree angle with respect to the second direction DR2. For example, the first direction DR1 is a direction that perpendicularly intersects the removal direction (e.g., the second direction DR2) of the protective tape 411 at 90 degrees, and each of the diagonal portions DG1′ to DG8′ of the second zigzag portion ZZ2 may be disposed to have an inclination that is not parallel to the first direction DR1.

The first diagonal portion DG1′ of the second zigzag portion ZZ2 may have a shape symmetrical to the first diagonal portion DG1 of the first zigzag portion ZZ1 with respect to the aforementioned vertical symmetry line.

The second diagonal portion DG2′ of the second zigzag portion ZZ2 may have a shape symmetrical to the second diagonal portion DG2 of the first zigzag portion ZZ1 with respect to the aforementioned vertical symmetry line.

The third diagonal portion DG3′ of the second zigzag portion ZZ2 may have a shape symmetrical to the third diagonal portion DG3 of the first zigzag portion ZZ1 with respect to the aforementioned vertical symmetry line.

The fourth diagonal portion DG4′ of the second zigzag portion ZZ2 may have a shape symmetrical to the fourth diagonal portion DG4 of the first zigzag portion ZZ1 with respect to the aforementioned vertical symmetry line.

The fifth diagonal portion DG5′ of the second zigzag portion ZZ2 may have a shape symmetrical to the fifth diagonal portion DG5 of the first zigzag portion ZZ1 with respect to the aforementioned vertical symmetry line.

The sixth diagonal portion DG6′ of the second zigzag portion ZZ2 may have a shape symmetrical to the sixth diagonal portion DG6 of the first zigzag portion ZZ1 with respect to the aforementioned vertical symmetry line.

The seventh diagonal portion DG7′ of the second zigzag portion ZZ2 may have a shape symmetrical to the seventh diagonal portion DG7 of the first zigzag portion ZZ1 with respect to the aforementioned vertical symmetry line.

The eighth diagonal portion DG8′ of the second zigzag portion ZZ2 may have a shape symmetrical to the eighth diagonal portion DG8 of the first zigzag portion ZZ1 with respect to the aforementioned vertical symmetry line.

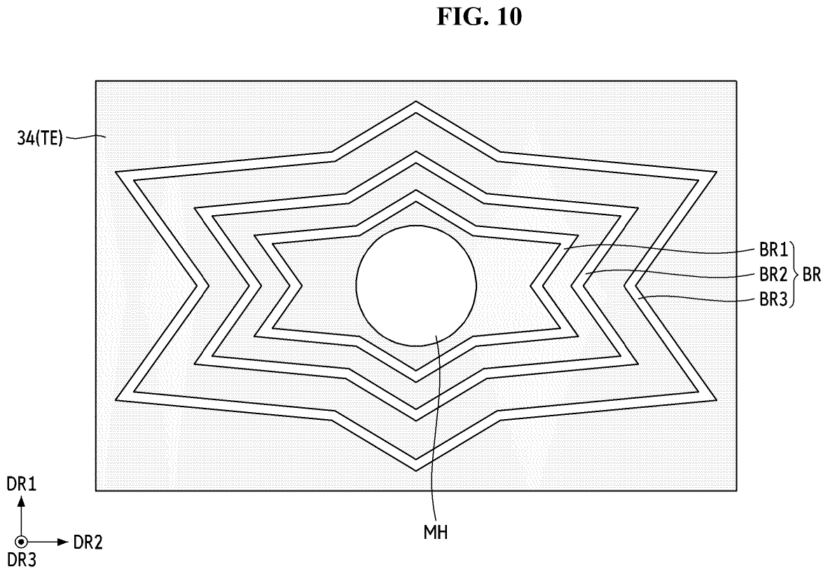

FIG. 10 is a plan view, i.e., a view in a direction orthogonal to a plane coincident with a surface of the display panel 100, of a portion of a display device according to another embodiment of the present disclosure. Specifically, FIG. 10 is a plan view of the module hole MH and the blocking groove BR around the module hole MH. In some examples, cross-sectional details of the blocking groove BR and the module hole MH may be as described above.

The display device of FIG. 10 differs from the display device of FIG. 8 described above in the shape of the module hole MH, and the following description will focus on this difference.

As shown in FIG. 10, the first blocking groove BR1, the second blocking groove BR2, and the third blocking groove BR3 may each have an enclosed shape with a series of bends along a length of the enclosed shape, where the enclosed shape surrounds the module hole MH.

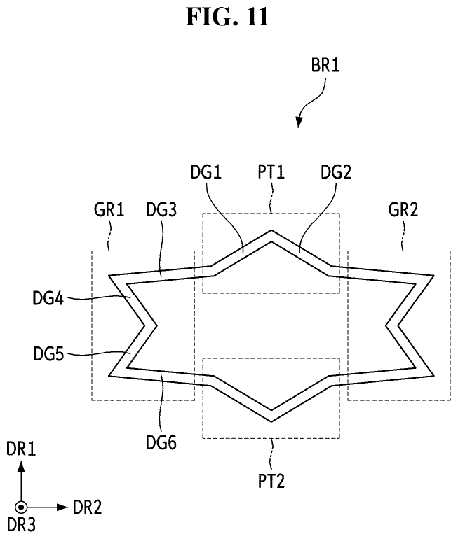

The shape of the blocking groove BR will be described in more detail with reference to FIG. 11. FIG. 11 is a diagram illustrating the first blocking groove BR1 of FIG. 10. Here, since the first blocking groove BR1, the second blocking groove BR2, and the third blocking groove BR3 have the same shape, the shape of the first blocking groove BR1 will be described in detail and will be considered as representative of the other blocking grooves, i.e., the second blocking groove BR2 and the third blocking groove BR3.

As shown in FIG. 11, the first blocking groove BR1 may include a first protrusion PT1, a second protrusion PT2, a first recess GR1, and a second recess GR2. The first protrusion PT1, the second protrusion PT2, the first recess GR1, and the second recess GR2 may be integrally formed. Because each protrusion and recess is a portion of the first blocking groove BT1, each may respectively be referred to as a portion as well. For example, the first protrusion PT1 may be a first protrusion portion, the first recess GR1 may be the first recess portion, and so on.

The first protrusion PT1 may protrude along the first direction DR1. In plan view, the first protrusion PT1 may have an apex that points away from the module hole. In some examples, in plan view, the first protrusion PT1 may have the shape of a triangle (e.g., an embossed triangle). The first protrusion PT1 may include a first diagonal portion DG1 and a second diagonal portion DG2 connected to each other. The first diagonal portion DG1 and the second diagonal portion DG2 may define the shape of the first protrusion PT1. For example, one side of the first diagonal portion DG1 and one side of the second diagonal portion DG2 may be connected to each other to define the first protrusion PT1 in a triangular shape. In other words, the first diagonal portion DG1 and the second diagonal portion DG2 may be connected to each other to have the shape of the first protrusion PT1. Each of the diagonal portions DG1 and DG2 of the first protrusion PT1 may have a shape inclined in a diagonal direction with respect to the second direction DR2 so as to be at an oblique angle with respect to the second direction DR2, i.e., not to form an angle of 90 degrees with respect to the second direction DR2. For example, the first direction DR1 is a direction that perpendicularly intersects the removal direction (e.g., the second direction DR2) of the protective tape 411 at 90 degrees, and each of the diagonal portions DG1 and DG2 of the first protrusion PT1 may be disposed to have an inclination that is not parallel to the first direction DR1.

The second protrusion PT2 may protrude in the reverse direction of the first direction DR1. In plan view, the second protrusion PT2 may have an apex that points away from the module hole. In some examples, in plan view, the second protrusion PT2 may have the shape of a triangle (e.g., an embossed triangle). The second protrusion PT2 may face the first protrusion PT1 in the first direction DR1. The second protrusion PT2 may have a shape symmetrical to the first protrusion PT1 with respect to an imaginary line (hereinafter, a horizontal symmetry line) that passes through the center of the first recess GR1 and the center of the second recess GR2. The second protrusion PT2 may have the same configuration as the first protrusion PT1 described above.

The first recess GR1 may be connected to one side of the first protrusion PT1 and one side of the second protrusion PT2. In plan view, the first recess GR1 may have an apex that points toward the module hole. In some examples, in plan view, the first recess GR1 may have the shape of a triangle (e.g., an engraved triangle). The first recess GR1 may include a third diagonal portion DG3, a fourth diagonal portion DG4, a fifth diagonal portion DG5, and a sixth diagonal portion DG6 connected to each other. One side of the third diagonal portion DG3 may be connected to the first diagonal portion DG1. One side of the fourth diagonal portion DG4 may be connected to the third diagonal portion DG3. One side of the fifth diagonal portion DG5 may be connected to the fourth diagonal portion DG4. One side of the sixth diagonal portion DG6 may be connected to the fifth diagonal portion DG5, and the other side of the sixth diagonal portion DG6 may be connected to the second protrusion PT2. The third to sixth diagonal portions DG3 to DG6 may define the shape of the first recess GR1. For example, one sides of the third to sixth diagonal portions DG3 to DG6 may be connected to each other to define the first recess GR1 in a triangular shape. In other words, the third to sixth diagonal portions DG3 to DG6 may be connected to each other to have the shape of the first recess GR1. Each of the diagonal portions DG3 to DG6 of the first recess GR1 may have a shape inclined in a diagonal direction with respect to the second direction DR2 so as not to form an angle of 90 degrees with respect to the second direction DR2. For example, the first direction DR1 is a direction that perpendicularly intersects the removal direction (e.g., the second direction DR2) of the protective tape 411 at 90 degrees, and each diagonal portion of the first recess GR1 may be disposed to have an inclination that is not parallel to the first direction DR1. In some examples, at least one of third diagonal portion DG3 and sixth diagonal portion DG6 is in alignment with second direction DR2.

The second recess GR2 may be connected to the other side of the first protrusion PT1 and the other side of the second protrusion PT2. In plan view, the second recess GR2 may have an apex that points toward the module hole. In some examples, in plan view, the second recess GR2 may have the shape of a triangle (e.g., an engraved triangle). The second recess GR2 may face the first recess GR1 in the second direction DR2. The second recess GR2 may have a shape symmetrical to the first recess GR1 with respect to an imaginary line (hereinafter, a vertical symmetry line) that passes through the center of the first protrusion PT1 and the center of the second protrusion PT2. The outer angle of the second recess GR2 may be the same as the outer angle of the first recess GR1. The second recess GR2 may have the same configuration as the first recess GR1 described above.

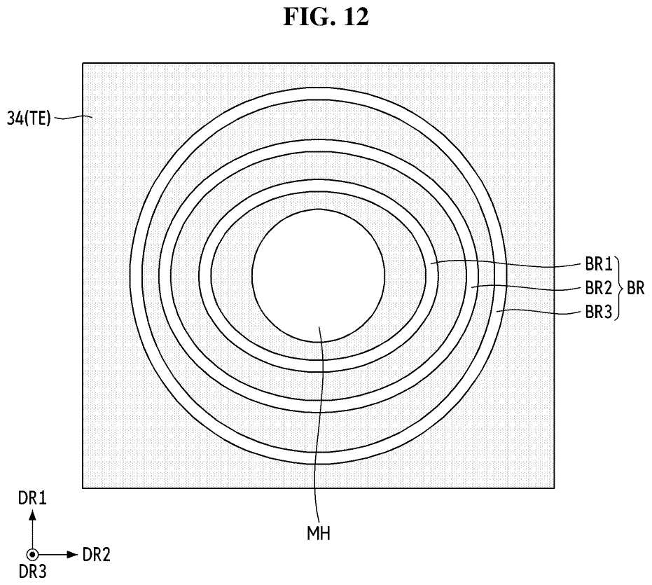

FIG. 12 is a plan view, i.e., a view in a direction orthogonal to a plane coincident with a surface of the display panel 100, of a display device according to another embodiment of the present disclosure. Specifically, FIG. 12 is a plan view of the module hole MH and the blocking groove BR around the module hole MH. In some examples, cross-sectional details of the blocking groove BR and the module hole MH may be as described above.

The display device of FIG. 12 differs from the display device of FIG. 8 described above in the shape of the module hole MH, and the following description will focus on this difference.

As shown in FIG. 12, the first blocking groove BR1, the second blocking groove BR2, and the third blocking groove BR3 may have different shapes. For example, in plan view, the first blocking groove BR1 and the second blocking groove BR2 may each have an elliptical shape, and the third blocking groove BR3 may have a circular shape. In this case, the further the blocking groove BR is disposed from the module hole MH, the smaller its eccentricity is. For example, between the first blocking groove BR1 and the second blocking groove BR2, the second blocking groove BR2, which is disposed farther from the module hole MH than first blocking groove BR1, may have a smaller eccentricity than the first blocking groove BR1. In other words, the eccentricity of the second blocking groove BR2 may be smaller than the eccentricity of the first blocking groove BR1. Meanwhile, the eccentricity of the third blocking groove BR3 may be 0. Therefore, in some examples where a plurality of blocking grooves are disposed around the module hole MH, the plurality of blocking grooves may have a smaller eccentricity as they are disposed farther from the module hole MH.

The blocking groove BR of the display panel 100 may be varied in many ways. In some embodiments, the blocking groove BR shown in FIG. 8 may include zig-zag portions with a different quantity of angled portions than that shown in FIG. 8. Similarly, protrusion portions and/or recess portions in the blocking groove BR of FIG. 10 may include a different quantity of angled portions than that shown in FIG. 10. Further, the blocking groove BR of FIG. 12 may include any number of elliptical blocking grooves, e.g., a greater number or a lesser number than that shown in FIG. 12.

According to some embodiments, when the protective tape 411 is previously disposed on the display panel 100 and is removed along the second direction DR2, long dimensions of the elliptical first blocking groove BR1 and the elliptical second blocking groove BR2, and indeed a majority of a length of the respective first and second blocking grooves BR1, BR2, has a curved surface with tangents that are at small angles relative to the second direction DR2.

FIG. 13 is a diagram illustrating the magnitude of resistance force of the protective tape 411 in regions A1, A2, A3, A4, and A5 of the blocking groove BR when the protective tape 411 is removed. In some examples, the principles described with respect to FIG. 13 may be applied in the same way to embodiments of the display device that include a blocking groove arrangement as shown in FIGS. 8-9.

As shown in FIG. 13, the protective tape 411 may be removed along a left to right direction (e.g., the second direction DR2 or a direction indicated by an arrow AR in FIG. 13). Meanwhile, when the protective tape 411 is removed, resistance may occur due to a bonding force between the protective tape 411 and the encapsulation layer TE. The magnitude of this resistance may vary depending on the removal direction of the protective tape 411 and the shape of the blocking groove BR. For purposes of this explanation, this resistance is defined as the resistance force of the protective tape 411.

The blocking groove BR includes horizontal portions HL, i.e., elongate portions extending in a direction aligned with the removal direction of the protective tape 411 in a third region A3 and a fifth region A5. Accordingly, among first to fifth regions A1 to A5, the resistance force of the protective tape 411 may be the smallest in the third region A3 and the fifth region A5.

The blocking groove BR may include diagonal portions DG disposed diagonally with respect to the second direction DR2 in the first region A1, the second region A2, and the fourth region A4. Since each of the diagonal portions DG is inclined at an angle other than 90 degrees with respect to the second direction DR2 in which the protective tape 411 is removed, the resistance force of the protective tape 411 may be reduced in the first region A1, the second region A2, and the fourth region A4. For example, the resistance force of the protective tape 411 may be reduced by a portion of the blocking groove BR being inclined in a diagonal direction rather than a direction aligned with first direction DR1. Meanwhile, the resistance force of the protective tape 411 in the first region A1, the second region A2, and the fourth region A4 may be greater than the resistance force of the protective tape 411 in the third region A3 and the fifth region A5 described above.

Through arrangements such as that described above and shown in FIG. 13, when the protective tape 411 is removed, the resistance force of the protective tape 411 may be reduced through the inclusion of the diagonal portions DG in the first zigzag portion ZZ1 and the second zigzag portion ZZ2. Therefore, when the protective tape 411 is removed, damage to the encapsulation layer TE may be prevented.

Additionally, the blocking groove BR of FIG. 10 described above also includes the plurality of diagonal portions DR1 to DR6, so that when the protective tape 411 is removed, damage to the encapsulation layer TE may be prevented by the blocking groove BR of FIG. 10.

Further, according to the embodiment of FIG. 12 described above, since the first blocking groove BR1 and the second blocking groove BR2 each have an elliptical shape with a long dimension along the second direction DR2, the tangents of curved portions facing each other in the second direction DR2 may have angles inclined mostly in a diagonal direction with respect to the second direction DR2. In other words, the tangents of the curved portions facing each other in the second direction DR2 may have inclinations in a diagonal direction rather than 90 degrees with respect to the second direction DR2. Therefore, when the protective tape 411 is removed, damage to the encapsulation layer TE may be prevented by the blocking groove BR of FIG. 12.

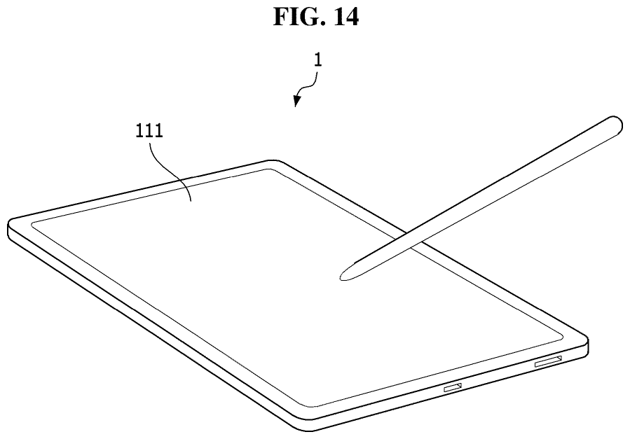

FIG. 14 is a perspective view showing an electronic device to which a display device according to one embodiment is applied.

Referring to FIG. 14, a tablet 1, to which a display device 111 according to one embodiment is applied, is illustrated as an example of an electronic device. However, the display device 111 is applicable not only to the tablet 1 but also to other electronic devices. For example, the display device 111 may be applied to an electronic device that displays a moving image or a still image. For example, the display device 10 according to one embodiment is applicable to portable electronic devices such as a mobile phone, a smartphone, a smartwatch, a watch phone, a mobile communication terminal, an electronic notebook, an electronic book, a portable multimedia player (PMP), a navigation device, and an ultra mobile PC (UMPC). Alternatively, the display device 111 according to one embodiment may be used as a display screen of various electronic devices such as a television, a laptop computer, a monitor, a billboard, or an Internet-of-Things (IOT) device.

Further, it should be appreciated that the display panel of the display device 111 that is contemplated for use in the aforementioned electronic devices may be any display panel contemplated by the present disclosure. For example, the display device 111 of FIG. 14 may include the aforementioned display panel 10 of FIGS. 1 to 13. The electronic device according to one embodiment includes the display device described above and may further include modules or devices having additional functions in addition to the display device.

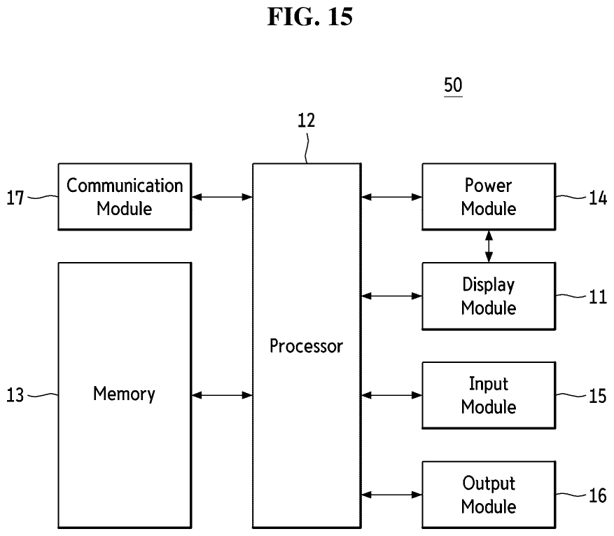

FIG. 15 is a block diagram of an electronic device according to one embodiment. Referring to FIG. 15, the electronic device 50 according to one embodiment may include a display module 11, a processor 12, a memory 13, and a power module 14. The electronic device 50 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 50 other than the display device.

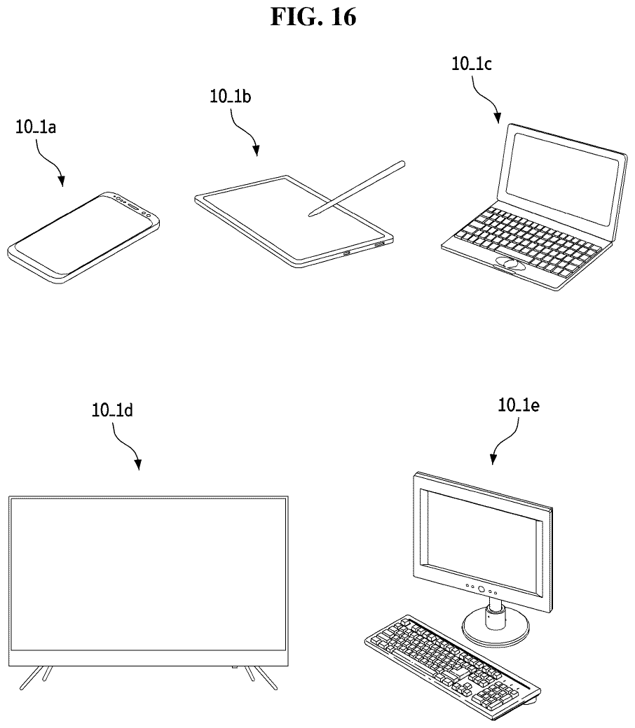

FIGS. 16, 17 and 18 are schematic diagrams of electronic devices according to various embodiments of the present disclosure. FIGS. 16 to 18 are examples of various electronic devices to which the display device according to the embodiments may be applied.

FIG. 16 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they may also include display modules and input modules similar to smartphones 10_1, and may additionally include communication modules in some cases.

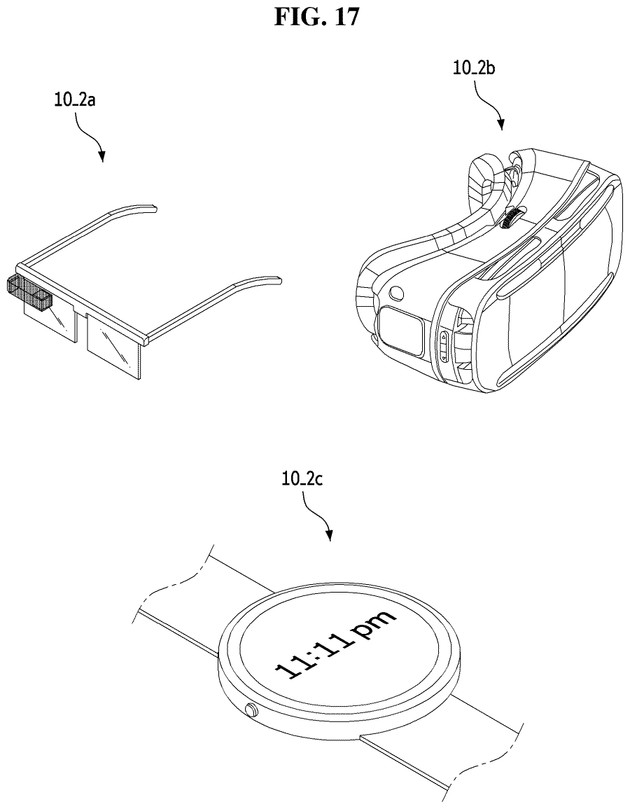

FIG. 17 shows an example of an electronic device including a display module being applied to a wearable electronic device. The wearable electronic device may be, for example, a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

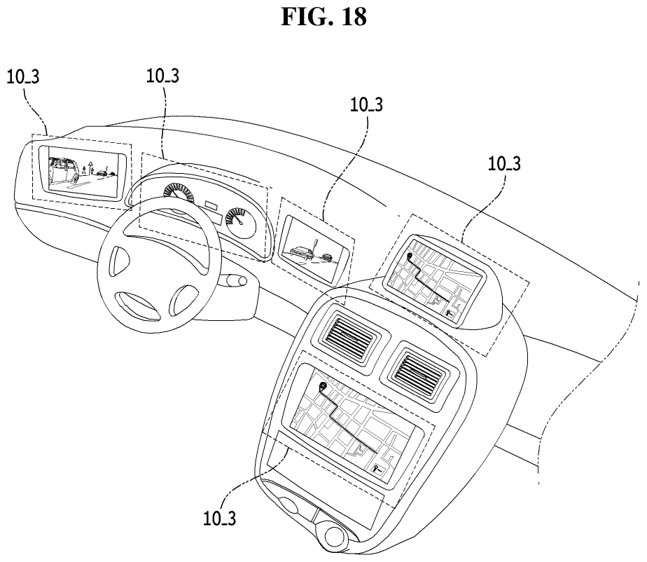

The smart watch 10_2c includes a biometric sensor as an input device, and may provide biometric information recognized by the biometric sensor to the user through the display module. FIG. 18 illustrates a case where an electronic device including a display module is applied to a vehicle. For example, the electronic device 10_3 may be applied to a dashboard, center fascia (console), etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the preferred embodiments without substantially departing from the principles of the present disclosure. Therefore, the disclosed preferred embodiments of the disclosure are used in a generic and descriptive sense only and not for purposes of limitation.

1. A display device comprising:
a display panel;
a module hole penetrating the display panel in a display area of the display panel; and
a blocking groove disposed on the display panel such that the blocking groove is disposed around the module hole, the blocking groove being recessed in the display area of the display panel,
wherein the blocking groove comprises:
a first elongate portion;
a second elongate portion disposed to face the first elongate portion such that the second elongate portion is on an opposite side of the module hole relative to the first elongate portion;
a first zigzag portion connected between a first side of the first elongate portion and a first side of the second elongate portion; and
a second zigzag portion connected between a second side of the first elongate portion and a second side of the second elongate portion and disposed to face the first zigzag portion,
wherein the second side of the first elongate portion is opposite the first side of the first elongate portion and the second side of the second elongate portion is opposite the first side of the second elongate portion.

2. The display device of claim 1, wherein the first elongate portion extends along a removal direction of a protective tape configured to be disposed on the display panel.

3. The display device of claim 1, wherein the second elongate portion extends along a removal direction of a protective tape configured to be disposed on the display panel.

4. The display device of claim 1, wherein the first zigzag portion further comprises a plurality of diagonal portions connected to each other in a zigzag shape.

5. The display device of claim 4, wherein each diagonal portion of the plurality of diagonal portions of the first zigzag portion has a shape inclined in a diagonal direction with respect to a removal direction of a protective tape configured to be disposed on the display device so as to form an oblique angle relative to the removal direction of the protective tape.

6. The display device of claim 1, wherein the second zigzag portion further comprises a plurality of diagonal portions connected to each other in a zigzag shape.

7. The display device of claim 6, wherein each diagonal portion of the plurality of diagonal portions of the second zigzag portion has a shape inclined in a diagonal direction with respect to a removal direction of a protective tape configured to be disposed on the display device so as to form an oblique angle relative to the removal direction of the protective tape.

8. The display device of claim 1, wherein the blocking groove surrounds the module hole when viewed in a direction orthogonal to a plane coincident with a surface of the display panel.

9. The display device of claim 1, wherein the blocking groove is a first blocking groove and the display device further comprises a second blocking groove disposed at a different distance from the module hole relative to the first blocking groove.

10. The display device of claim 9, wherein a shape of the first blocking groove and the second blocking groove is the same.

11. The display device of claim 9, wherein the first blocking groove and the second blocking groove have different lengths.

12. The display device of claim 1, wherein the module hole has a circular shape when viewed in a direction orthogonal to a plane coincident with a surface of the display panel.

13. The display device of claim 1, wherein an entirety of the first elongate portion is linear.

14. The display device of claim 1, wherein the first elongate portion is parallel to the second elongate portion.

15. A display device comprising:
a display panel;
a module hole penetrating the display panel in a display area of the display panel; and
a blocking groove disposed on the display panel such that the blocking groove is disposed around the module hole, the blocking groove being recessed in the display area of the display panel,
wherein the blocking groove comprises:
a first protrusion portion, wherein an apex of the first protrusion portion points away from the module hole;
a second protrusion portion disposed opposite the first protrusion portion such that the module hole is in between the second protrusion portion and the first protrusion portion, wherein an apex of the second protrusion portion points away from the module hole;
a first recess portion connected to a first side of the first protrusion portion and a first side of the second protrusion portion, wherein an apex of the first recess portion points toward the module hole; and
a second recess portion connected to a second side of the first protrusion portion and a second side of the second protrusion portion, wherein an apex of the second recess portion points toward the module hole,
wherein the second side of the first protrusion portion is opposite the first side of the first protrusion portion and the second side of the second protrusion portion is opposite the first side of the second protrusion portion.

16. The display device of claim 15, wherein the first protrusion portion further comprises a plurality of diagonal portions connected to define a shape of the first protrusion portion.

17. The display device of claim 16, wherein each diagonal portion of the plurality of diagonal portions of the first protrusion portion has a shape inclined in a diagonal direction with respect to a removal direction of a protective tape configured to be disposed on the display panel so as to form an oblique angle relative to the removal direction of the protective tape.

18. The display device of claim 15, wherein the first recess portion further comprises a plurality of diagonal portions connected to define a shape of the first recess portion.

19. The display device of claim 18, wherein each diagonal portion of the plurality of diagonal portions has a shape inclined in a diagonal direction with respect to a removal direction of a protective tape configured to be disposed on the display panel so as to form an oblique angle relative to the removal direction of the protective tape.

20. An electronic device comprising:
a display device configured for use as a screen, the display device comprising:
a display panel;
a module hole penetrating the display panel in a display area of the display panel; and
a blocking groove disposed on the display panel such that the blocking groove is disposed around the module hole, the blocking groove being recessed in the display area of the display panel,
wherein the blocking groove comprises:
a first elongate portion;
a second elongate portion disposed to face the first elongate portion such that the second elongate portion is on an opposite side of the module hole relative to the first elongate portion;
a first zigzag portion connected between a first side of the first elongate portion and a first side of the second elongate portion; and
a second zigzag portion connected between a second side of the first elongate portion and a second side of the second elongate portion and disposed to face the first zigzag portion,
wherein the second side of the first elongate portion is opposite the first side of the first elongate portion and the second side of the second elongate portion is opposite the first side of the second elongate portion.
